(19) United States
(12) Patent Application Publication
(10) Pub. No.: US 2025/0212564 A1
(43) Pub. Date: Jun. 26, 2025

(54) LIGHT EMITTING ELEMENT ARRAY SUBSTRATE AND MANUFACTURING METHOD THEREOF

(71) Applicant: AUO Corporation, Hsinchu (TW)

(72) Inventors: Kuan-Yi Lee, Hsinchu (TW); Wei-Chieh Chen, Hsinchu (TW); Chien-Hung Kuo, Hsinchu (TW)

(73) Assignee: AUO Corporation, Hsinchu (TW)

(21) Appl. No.: 18/399,692

(22) Filed: Dec. 29, 2023

(30) Foreign Application Priority Data
Dec. 20, 2023 (TW) 112149877

(51) Int. Cl. H01L 33/38; H01L 25/075

(52) U.S. Cl. CPC H10H 20/8312; H01L 25/0753

(57) ABSTRACT

A light emitting element array substrate includes a temporary storage base, light emitting elements, and adhesive structures. The light emitting elements are disposed on the temporary storage base. The adhesive structures are respectively located on the light emitting elements. Each of the adhesive structures includes a first adhesive member and a second adhesive member stacked on the first adhesive member. In addition, a manufacturing method of the light emitting element array substrate is also provided.

### CROSS-REFERENCE TO RELATED APPLICATION

This application claims the priority benefit of Taiwan application serial no. 112149877, filed on Dec. 20, 2023. The entirety of the above-mentioned patent application is hereby incorporated by reference herein and made a part of this specification.

### BACKGROUND

### Technical Field

The disclosure relates to an array substrate and a manufacturing method thereof, and in particular to a light emitting element array substrate and a manufacturing method thereof.

### Description of Related Art

A light emitting diode display panel includes a driving backplate and multiple light emitting diode elements transposed to the driving backplate. Inheriting characteristics of a light emitting diode, the light emitting diode display panel has advantages such as power saving, high efficiency, high brightness, and fast response time. In addition, compared with an organic light emitting diode display panel, the light emitting diode display panel also has advantages such as easy color adjustment, long light emitting life, and no image imprinting. Therefore, the light emitting diode display panel is regarded as the next generation of display technology. During a manufacturing process of the light emitting diode display panel, the light emitting diode elements must be transposed multiple times to enable the light emitting diode elements to be bonded to the driving backplate. However, as the number of transpositions increases, the overall offset of the light emitting diode elements continues to accumulate, which causes the bonding yield of the light emitting diode elements and the driving backplate to decrease.

### SUMMARY

The disclosure provides a light emitting element array substrate in which an offset of a light emitting element is small.

The disclosure provides a manufacturing method of a light emitting element array substrate, which can manufacture a light emitting element array substrate in which an offset of a light emitting element is small.

A light emitting element array substrate of the disclosure includes a temporary storage base, multiple light emitting elements, and multiple adhesive structures. The light emitting elements are disposed on the temporary storage base. The adhesive structures are respectively located on the light emitting elements. Each of the adhesive structures includes a first adhesive member and a second adhesive member stacked on each other.

A manufacturing method of a light emitting element array substrate of the disclosure includes the following steps. Multiple first light emitting element supply substrates are provided. Each of the first light emitting element supply substrates includes a first temporary storage base, a light emitting element, and a first adhesive member, and the first adhesive member is disposed between the light emitting element and the first temporary storage base. A second temporary storage base and a first adhesive layer on the second temporary storage base are provided. An area of the second temporary storage base is greater than an area of the first temporary storage base. Multiple light emitting elements and multiple first adhesive members of the first light emitting element supply substrates are transposed to the first adhesive layer on the second temporary storage base to form a second light emitting element supply substrate. The second light emitting element supply substrate includes the second temporary storage base, the first adhesive layer, the light emitting elements, and the first adhesive members, and each of the light emitting elements is located between a corresponding one of the first adhesive members and the first adhesive layer. A third temporary storage base and a second adhesive layer on the third temporary storage base are provided. The light emitting elements and the first adhesive members of the second light emitting element supply substrate are transposed to the second adhesive layer on the third temporary storage base, so that the first adhesive members are located between the light emitting elements and the second adhesive layer, and the second adhesive layer is located between the first adhesive members and the third temporary storage base.

### BRIEF DESCRIPTION OF THE DRAWINGS

FIG. 1A to FIG. 1H are cross-sectional schematic views of a manufacturing process of a display device according to an embodiment of the disclosure.

FIG. 2A to FIG. 2C are cross-sectional schematic views of a manufacturing process of a light emitting element array substrate according to another embodiment of the disclosure.

FIG. 3A to FIG. 3C are cross-sectional schematic views of a manufacturing process of a light emitting element array substrate according to yet another embodiment of the disclosure.

FIG. 4 is a partial cross-sectional enlarged schematic view of a light emitting element array substrate according to yet another embodiment of the disclosure.

FIG. 5 is a partial cross-sectional enlarged schematic view of a light emitting element array substrate according to still another embodiment of the disclosure.

FIG. 6 is a partial cross-sectional enlarged schematic view of a light emitting element array substrate according to an embodiment of the disclosure.

FIG. 7 is a partial cross-sectional enlarged schematic view of a light emitting element array substrate according to another embodiment of the disclosure.

FIG. 8 is a partial cross-sectional enlarged schematic view of a light emitting element array substrate according to yet another embodiment of the disclosure.

FIG. 9 is a partial cross-sectional enlarged schematic view of a light emitting element array substrate according to still another embodiment of the disclosure.

FIG. 10 is a partial cross-sectional enlarged schematic view of a light emitting element array substrate according to an embodiment of the disclosure.

### DESCRIPTION OF THE EMBODIMENTS

Reference will now be made in detail to the exemplary embodiments of the disclosure, and examples of the exemplary embodiments are illustrated in the drawings. Wherever possible, the same reference numerals are used in the drawings and the description to refer to the same or similar parts.

It should be understood that when an element such as a layer, a film, a region, or a substrate is referred to as being “on” another element or “connected to” another element, the element may be directly on the another element or connected to the another element, or there may be an intermediate element. In contrast, when an element is referred to as being “directly on” another element or “directly connected to” another element, there is no intermediate element. As used herein, “connection” may refer to physical and/or electrical connection. Furthermore, “electrical connection” or “coupling” may be that there is another element between two elements.

As used herein, “about”, “approximately”, or “substantially” includes the stated value and an average value within an acceptable deviation range of the particular value as determined by persons skilled in the art, while taking into account the measurement in discussion and a particular amount of error (that is, the limitation of a measurement system) associated with the measurement. For example, “about” may mean within one or more standard deviations or within +30%, +20%, +10%, or +5% of the stated value. Furthermore, “about”, “approximately”, or “substantially” used herein may choose a more acceptable deviation range or standard deviation according to optical properties, etching properties, or other properties and may not apply one standard deviation to all properties.

Unless otherwise defined, all terms (including technical and scientific terms) used herein have the same meaning as commonly understood by persons skilled in the art to which the disclosure belongs. It should be understood that the terms, such as those defined in commonly used dictionaries, should be interpreted as having meanings consistent with the prior art and the context of the disclosure, and should be interpreted in an idealized or overly formal manner, unless specifically defined herein.

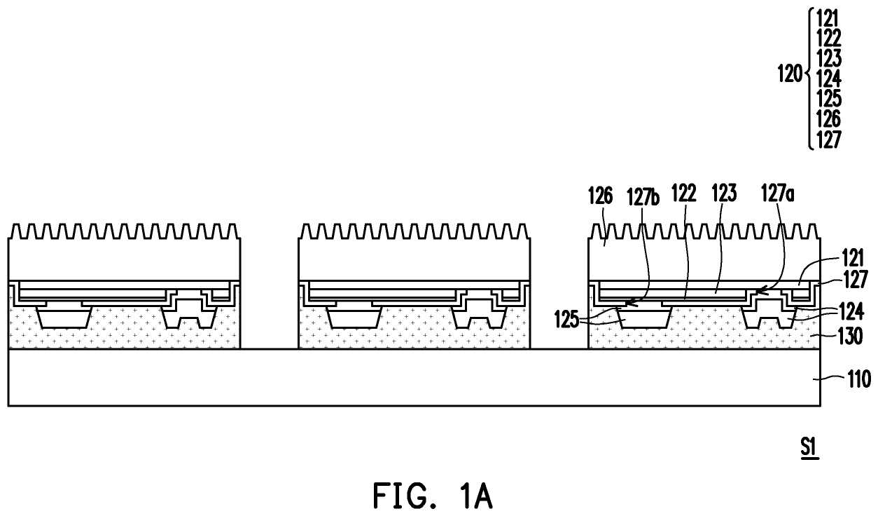

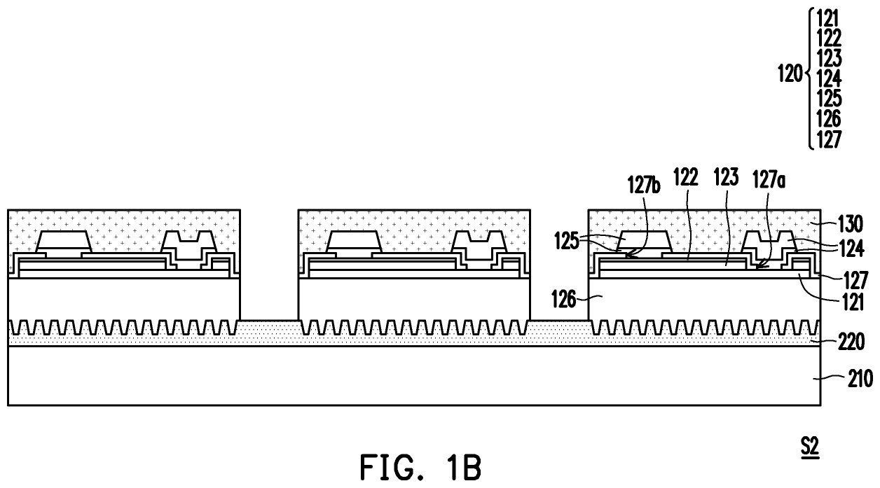

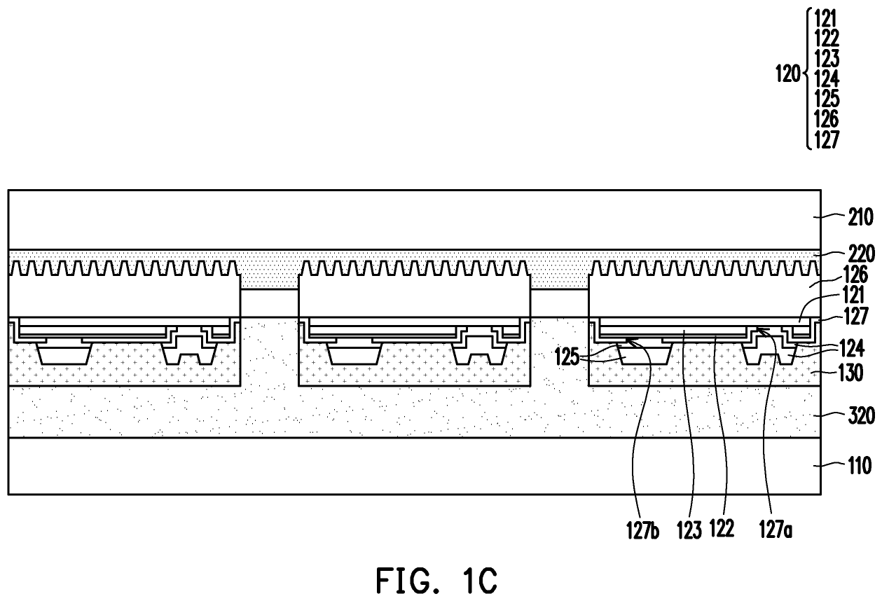

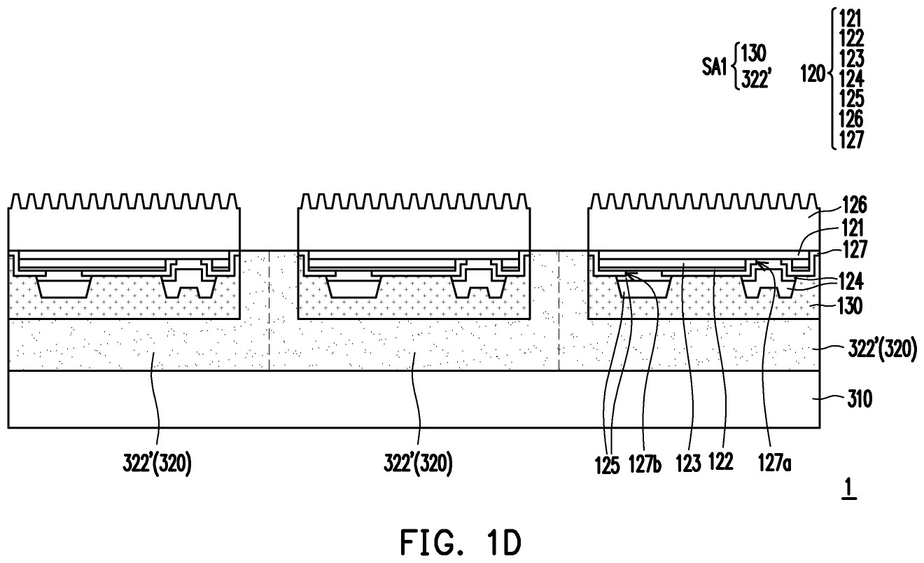

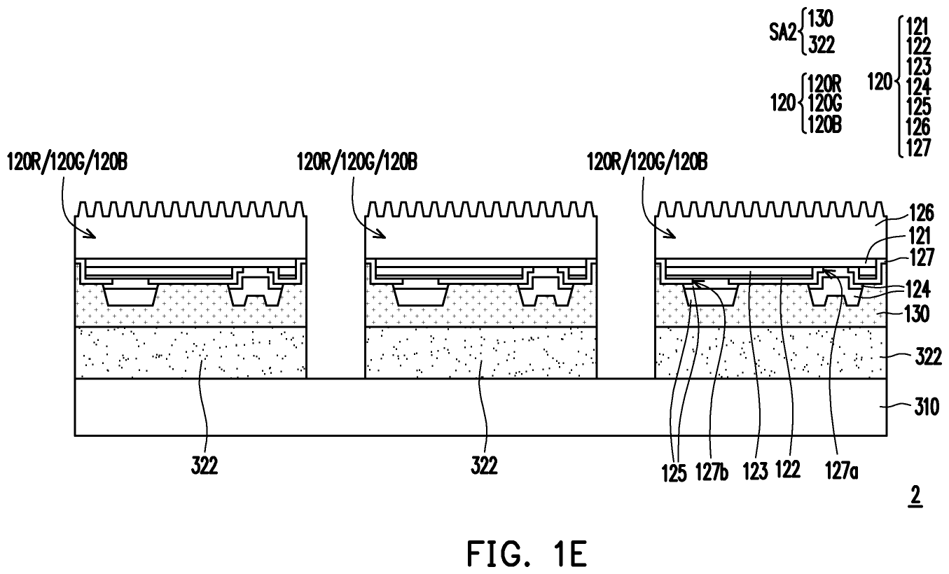

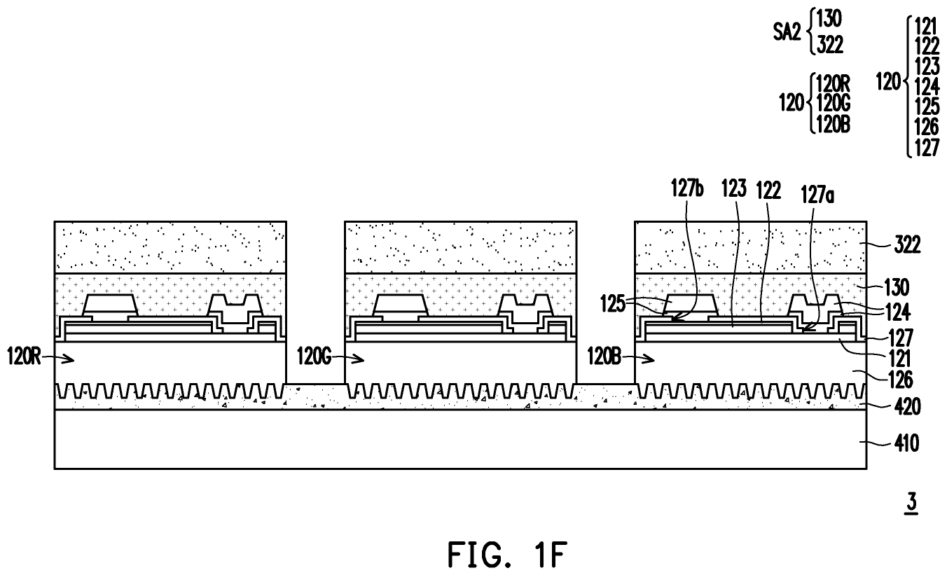

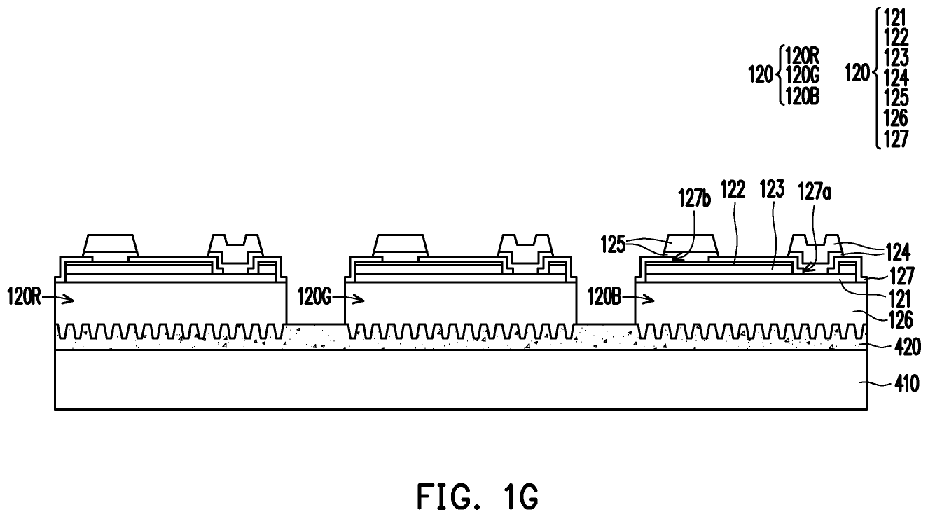

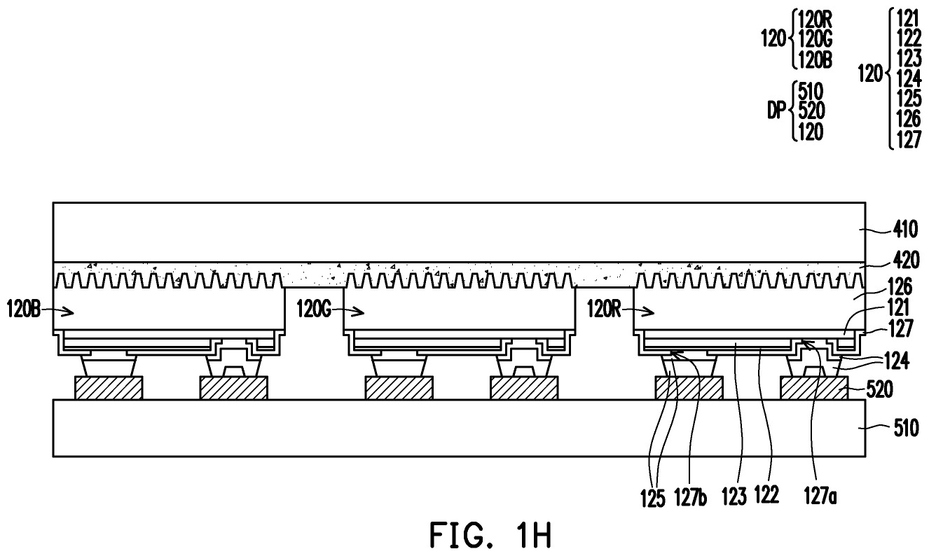

FIG. 1A to FIG. 1H are cross-sectional schematic views of a manufacturing process of a display device according to an embodiment of the disclosure. Please refer to FIG. 1A. First, multiple first light emitting element supply substrates S1 are provided. FIG. 1A shows one first light emitting element supply substrate S1 as a representative. Each first light emitting element supply substrate S1 includes a first temporary storage base 110, multiple light emitting elements 120, and multiple first adhesive members 130. The first adhesive members 130 are disposed between the light emitting elements 120 and the first temporary storage base 110. The first adhesive members 130 are disposed on the first temporary storage base 110 and are separated from each other, and the light emitting elements 120 are respectively disposed on the first adhesive members 130.

In an embodiment, each light emitting element 120 includes a first semiconductor layer 121, a second semiconductor layer 122, an active layer 123 disposed between the first semiconductor layer 121 and the second semiconductor layer 122, and multiple electrodes 124 and 125 respectively electrically connected to the first semiconductor layer 121 and the second semiconductor layer 122. In an embodiment, the light emitting element 120 is, for example, a micro light emitting diode (uLED).

In an embodiment, each light emitting element 120 may also optionally include an epitaxial layer 126, the first semiconductor layer 121 is formed on the epitaxial layer 126, and the first semiconductor layer 121 is located between the epitaxial layer 126 and the active layer 123. For example, in an embodiment, the epitaxial layer 126 may be undoped gallium nitride, the first semiconductor layer 121 may be n-type gallium nitride, the active layer 123 may be a multi-quantum well layer, and the second semiconductor layer 122 may be p-type gallium nitride, but the disclosure is not limited thereto.

In an embodiment, each light emitting element 120 may also optionally include an insulating layer 127. The insulating layer 127 is disposed on the second semiconductor layer 122 and has multiple contact windows 127a and 127b respectively overlapping with the first semiconductor layer 121 and the second semiconductor layer 122. The electrodes 124 and 125 are respectively electrically connected to the first semiconductor layer 121 and the second semiconductor layer 122 through the contact windows 127a and 127b of the insulating layer 127.

Please refer to FIG. 1A and FIG. 1B. Next, a second temporary storage base 210 and a first adhesive layer 220 on the second temporary storage base 210 are provided, wherein the area of the second temporary storage base 210 is larger than the area of the first temporary storage base 110. The shape of the second temporary storage base 210 may be different from the shape of the first temporary storage base 110. For example, in an embodiment, the first temporary storage base 110 is, for example, a 6-inch circular base, and the second temporary storage base 210 is, for example, a 14-inch, 20-inch, or 26-inch square base, but the disclosure is not limited thereto. In an embodiment, the first adhesive layer 220 may cover the entire second temporary storage base 210, but the disclosure is not limited thereto.

Please refer to FIG. 1A and FIG. 1B. Then, the light emitting elements 120 and the first adhesive members 130 of the first light emitting element supply substrates S1 are transposed to the first adhesive layer 220 on the second temporary storage base 210 to form a second light emitting element supply substrate S2. For example, in an embodiment, the first adhesive member 130 is separated from the first temporary storage base 110 using laser lift-off (LLO), so that the first adhesive member 130 and the light emitting element 120 are transposed to the first adhesive layer 220.

It should be noted that the light emitting elements 120 and the first adhesive members 130 of the first light emitting element supply substrate S1 are sequentially transposed to the first adhesive layer 220. Specifically, the light emitting elements 120 and the first adhesive members 130 of one first light emitting element supply substrate S1 may be transposed to a place of the first adhesive layer 220 at a first time point. After that, at a second time point following the first time point, the light emitting elements 120 and the first adhesive members 130 of the next first light emitting element supply substrate S1 are transposed to another place of the first adhesive layer 220, thereby forming the second light emitting element supply substrate S2. FIG. 1A and FIG. 1B illustrate an example of transposing the light emitting elements 120 and the first adhesive members 130 of one first light emitting element supply substrate S1 to a place of the first adhesive layer 220.

Please refer to FIG. 1B. The second light emitting element supply substrate S2 includes the second temporary storage base 210, the first adhesive layer 220, the light emitting elements 120, and the first adhesive members 130, wherein each light emitting element 120 is located between a corresponding one of the first adhesive members 130 and the first adhesive layer 220, and the first adhesive layer 220 is located between the light emitting elements 120 and the second temporary storage base 210. In an embodiment, the first adhesive layer 220 may cover the entire second temporary storage base 210, but the disclosure is not limited thereto.

Please refer to FIG. 1C. Next, a third temporary storage base 310 and a second adhesive layer 320 on the third temporary storage base 310 are provided. In an embodiment, the second adhesive layer 320 may cover the entire third temporary storage base 310, but the disclosure is not limited thereto.

Please refer to FIG. 1B, FIG. 1C, and FIG. 1D. Then, the light emitting elements 120 and the first adhesive members 130 of the second light emitting element supply substrate S2 are transposed to the second adhesive layer 320 on the third temporary storage base 310, so that the first adhesive members 130 are located between the light emitting elements 120 and the second adhesive layer 320, and the second adhesive layer 320 is located between the first adhesive members 130 and the third temporary storage base 310.

Please refer to FIG. 1C and FIG. 1D. For example, in an embodiment, the light emitting element 120 is separated from the second temporary storage base 210 using laser lift-off (LLO), so that the light emitting element 120 and the first adhesive member 130 are transposed to the second adhesive layer 320, but the disclosure is not limited thereto.

Please refer to FIG. 1D. The third temporary storage base 310, the second adhesive layer 320, the first adhesive members 130, and the light emitting elements 120 may form a light emitting element array substrate 1. The light emitting element array substrate 1 includes the third temporary storage base 310, the light emitting elements 120 disposed on the third temporary storage base 310, and multiple adhesive structures SA1 respectively located on the light emitting elements 120, wherein each adhesive structure SA1 includes the first adhesive member 130 and a second adhesive member 322′ stacked on each other.

In an embodiment, the adhesive structure SA1 and the electrodes 124 and 125 of the light emitting element 120 are disposed on the same side of the active layer 123 of the light emitting element 120. In an embodiment, the adhesive structures SAL are disposed between the light emitting elements 120 and the third temporary storage base 310. In an embodiment, the second adhesive members 322′ of the adhesive structures SA1 may be multiple regions of the second adhesive layer 320 that respectively overlap with the first adhesive members 130, and the second adhesive members 322′ are directly connected. In an embodiment, the second adhesive layer 320 is, for example, thermal polyimide, but the disclosure is not limited thereto.

Please refer to FIG. 1D and FIG. 1E. Next, the second adhesive layer 320 on the third temporary storage base 310 may be patterned to form multiple second adhesive members 322 separated from each other, wherein the first adhesive members 130 are located between the light emitting elements 120 and the second adhesive members 322, and the second adhesive members 322 are located between the first adhesive members 130 and the third temporary storage base 310. For example, in an embodiment, the light emitting elements 120 may be used as hard masks, and a dry etching process is performed on the second adhesive layer 320 to form the second adhesive members 322 separated from each other.

Please refer to FIG. 1E. A light emitting element array substrate 2 includes the third temporary storage base 310, the light emitting elements 120 disposed on the third temporary storage base 310, and multiple adhesive structures SA2 respectively located on the light emitting elements 120, wherein each adhesive structure SA2 includes the first adhesive member 130 and the second adhesive member 322 stacked on each other. In an embodiment, the adhesive structures SA2 are separated from each other.

Please refer to FIG. 1E and FIG. 1F. Then, the light emitting elements 120 and the adhesive structures SA2 on the third temporary storage base 310 are optionally transposed to an adhesive layer 420 on a fourth temporary storage base 410, thereby forming another light emitting element array substrate 3. For example, in an embodiment, the adhesive structure SA2 is separated from the third temporary storage base 310 using laser lift-off (LLO), so that the adhesive structure SA2 and the light emitting element 120 are transposed to the adhesive layer 420 on the fourth temporary storage base 410, thereby forming the light emitting element array substrate 3.

The arrangement of the light emitting elements 120 of the light emitting element array substrate 2 is different from the arrangement of the light emitting elements 120 of another light emitting element array substrate 3. The arrangement of the light emitting elements 120 of another light emitting element array substrate 3 is determined according to positions of pads 520 (shown in FIG. 1H) of a driving backplate 510 (shown in FIG. 1H) of a display device DP (shown in FIG. 1H) to be formed.

It should be noted that the light emitting elements 120 shown in FIG. 1E are multiple light emitting elements 120R, 120G, or 120B for emitting the same color. The method shown in FIG. 1A to FIG. 1E may be repeatedly used to form various light emitting element array substrates 2, wherein each light emitting element array substrate 2 includes the light emitting elements 120R, 120G, or 120B for emitting beams of a single color. After repeatedly using the method shown in FIG. 1A to FIG. 1E to form the various light emitting element array substrates 2 for emitting beams of various colors, the light emitting elements 120R of one of the light emitting element array substrates 2, the light emitting elements 120G of another light emitting element array substrate 2, and the light emitting elements 120B of still another light emitting element array substrate 2 are respectively optionally transposed to the adhesive layer 420 on the fourth temporary storage base 410 to form the light emitting element array substrate 3 including the various light emitting elements 120R, 120G, and 120B, wherein the light emitting elements 120R, 120G, and 120B of the light emitting element array substrate 3 are configured to emit beams of different colors. For example, in an embodiment, the light emitting elements 120R, 120G, and 120B of the light emitting element array substrate 3 may be configured to emit red light, green light, and blue light, but the disclosure is not limited thereto.

Please refer to FIG. 1F. The light emitting element array substrate 3 includes the fourth temporary storage base 410, the light emitting elements 120R, 120G, and 120B disposed on the fourth temporary storage base 410, and the adhesive structures SA2 respectively located on the light emitting elements 120R, 120G, and 120B, wherein each adhesive structure SA2 includes the first adhesive member 130 and the second adhesive member 322 stacked on each other. The light emitting elements 120R, 120G, and 120B are disposed between the adhesive structures SA2 and the fourth temporary storage base 410. The light emitting element array substrate 3 further includes the adhesive layer 420 disposed on the fourth temporary storage base 410, wherein the light emitting elements 120R, 120G, and 120B are disposed on the adhesive layer 420, the light emitting elements 120R, 120G, and 120B are located between the adhesive structures SA2 and the adhesive layer 420, and the adhesive layer 420 is located between the light emitting elements 120R, 120G, and 120B and the fourth temporary storage base 410.

Please refer to FIG. 1F and FIG. 1G. Next, the adhesive structures SA2 on the light emitting elements 120R, 120G, and 120B are removed to expose the electrodes 124 and 125 of the light emitting elements 120R, 120G, and 120B. For example, in an embodiment, the adhesive structures SA2 on the light emitting elements 120R, 120G, and 120B may be removed using a dry etching process.

Please refer to FIG. 1G and FIG. 1H. Next, the light emitting elements 120R, 120G, and 120B on the fourth temporary storage base 410 are transposed to the driving backplate 510, and the electrodes 124 and 125 of the light emitting elements 120R, 120G, and 120B are electrically connected to the pads 520 of the driving backplate 510 to form the display device DP. The display device DP includes the driving backplate 510 and the light emitting elements 120R, 120G, and 120B, wherein the pads 520 of the driving backplate 510 are electrically connected to the electrodes 124 and 125 of the light emitting elements 120R, 120G, and 120B. For example, in an embodiment, the electrodes 124 and 125 of the light emitting elements 120R, 120G, and 120B may be electrically connected to the pads 520 of the driving backplate 510 using a laser bonding process.

It is worth mentioning that as mentioned above, the light emitting elements 120 are first transposed from multiple small-area first temporary storage bases 110 to the same large-area second temporary storage base 210, then simultaneously transposed from the same second temporary storage base 210 to the same third temporary storage base 310, and then optionally transposed from the same third temporary storage base 310 to the fourth temporary storage base 410. The light emitting elements 120R, 120G, or 120B transposed to the fourth temporary storage base 310 and configured to emit beams of the same color come from the same large-area third temporary storage base 310. Therefore, during the process of transposing the light emitting elements 120R, 120G, or 120B for emitting beams of the same color, the fourth temporary storage base 410 only needs to be aligned with the same large third temporary storage base 310, without the need to be aligned with multiple small temporary storage bases. Thereby, the overall offset of the light emitting elements 120R, 120G, and 120B on the fourth temporary storage base 410 can be greatly reduced, thereby improving the bonding yield of the light emitting elements 120R, 120G, and 120B and the driving backplate 510. In addition, the speed of transposition can also be improved.

It must be noted here that the following embodiments continue to use the reference numerals and some content of the foregoing embodiment, wherein the same numerals are adopted to represent the same or similar elements, and the description of the same technical content is omitted. For the description of the omitted part, reference may be made to the foregoing embodiment and will not be repeated in the following embodiments.

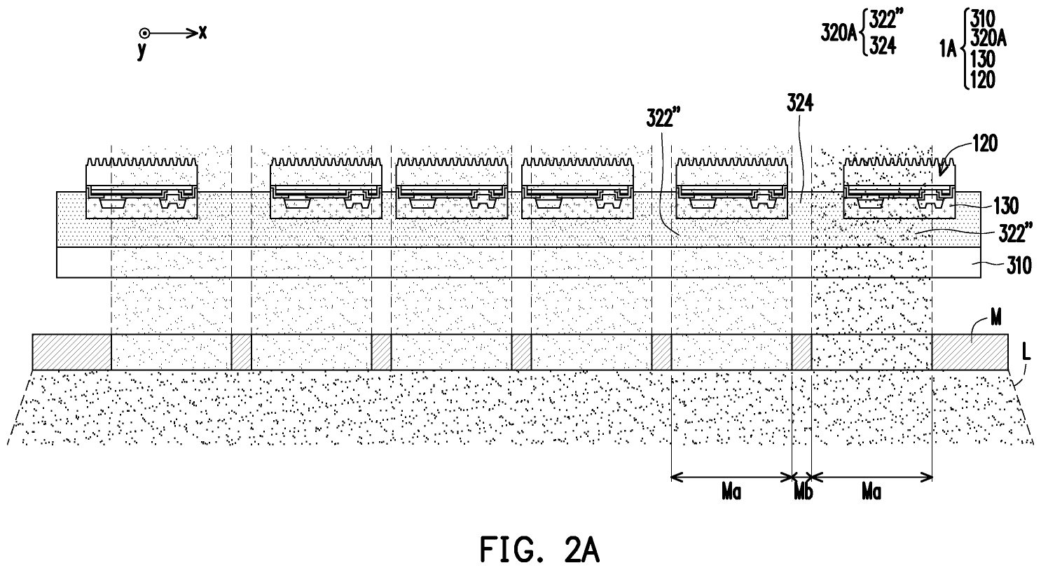

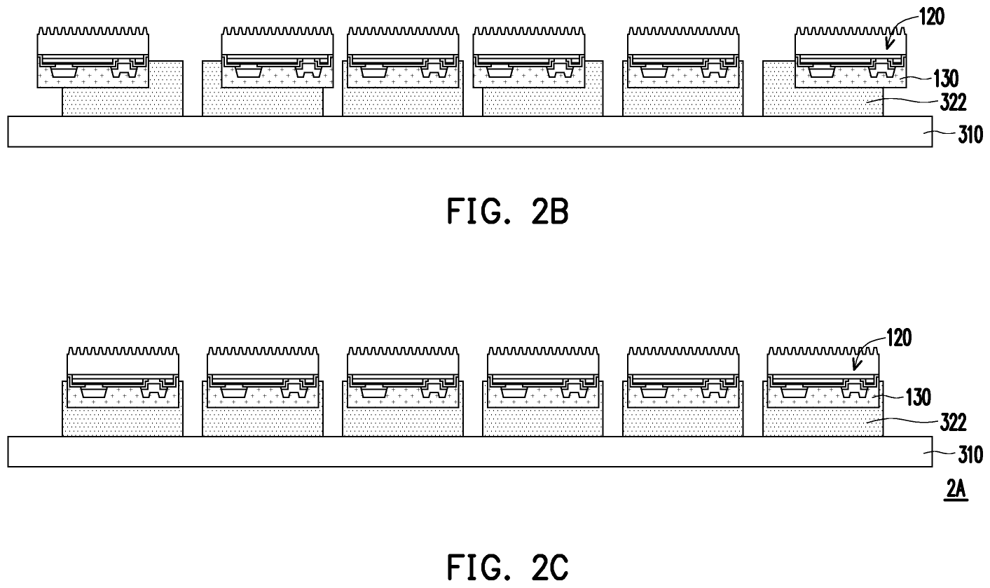

FIG. 2A to FIG. 2C are cross-sectional schematic views of a manufacturing process of a light emitting element array substrate according to another embodiment of the disclosure. A manufacturing method of a light emitting element array substrate 2A shown in FIG. 2A to FIG. 2C may be used to replace the manufacturing method of the light emitting element array substrate 2 shown in FIG. 1D to FIG. 1E. The manufacturing method of the light emitting element array substrate 2A is described below with reference to FIG. 2A to FIG. 2C.

Please refer to FIG. 2A. A second adhesive layer 320A of a light emitting element array substrate 1A has multiple first areas 322″ respectively corresponding to the light emitting elements 120 and a second area 324 between the first areas 322″. In the embodiment, the material of the second adhesive layer 320A of the light emitting element array substrate 1A is photosensitive and may be patterned using a photolithography process.

Please refer to FIG. 2A, FIG. 2B, and FIG. 2C. Specifically, in the embodiment, a mask M may be provided. The mask M has multiple first mask areas Ma corresponding to the first areas 322″ of the second adhesive layer 320A and a second mask area Mb corresponding to the second area 324 of the second adhesive layer 320A, wherein one of the first mask area Ma and the second mask area Mb (for example, the first mask area Ma) is light transmissive, and the other one of the first mask area Ma and the second mask area Mb (for example, the second mask area Mb) is non-light transmissive. Then, an exposure process is performed on the second adhesive layer 320A using the mask M. Then, a developing process is performed to remove the second area 324 of the second adhesive layer 320A, so that the first areas 322″ of the second adhesive layer 320A form the second adhesive members 322 separated from each other. Then, a thermal curing process is performed on the second adhesive members 322 to form the light emitting element array substrate 2A. It is worth mentioning that during the thermal curing process, since the materials of the first adhesive member 130 and the second adhesive member 322 are similar and compatible with each other, the first adhesive member 130 and the second adhesive member 322 are aligned with each other, thereby driving the light emitting element 120 on the first adhesive member 130 to be aligned with the second adhesive member 322. Thereby, the offset of the light emitting element 120 can be further reduced.

Please refer to FIG. 2A. In the embodiment, the irradiation range of a beam L used in the exposure process may exceed or shrink within 5 μm of the edge of the light emitting element 120 in a direction x, and exceed or shrink within 5 μm of the edge of the light emitting element 120 in a direction y, wherein the directions x and y are parallel to the third temporary storage base 310 and intersect each other. The beam L used in the exposure process is, for example, ultraviolet light or laser.

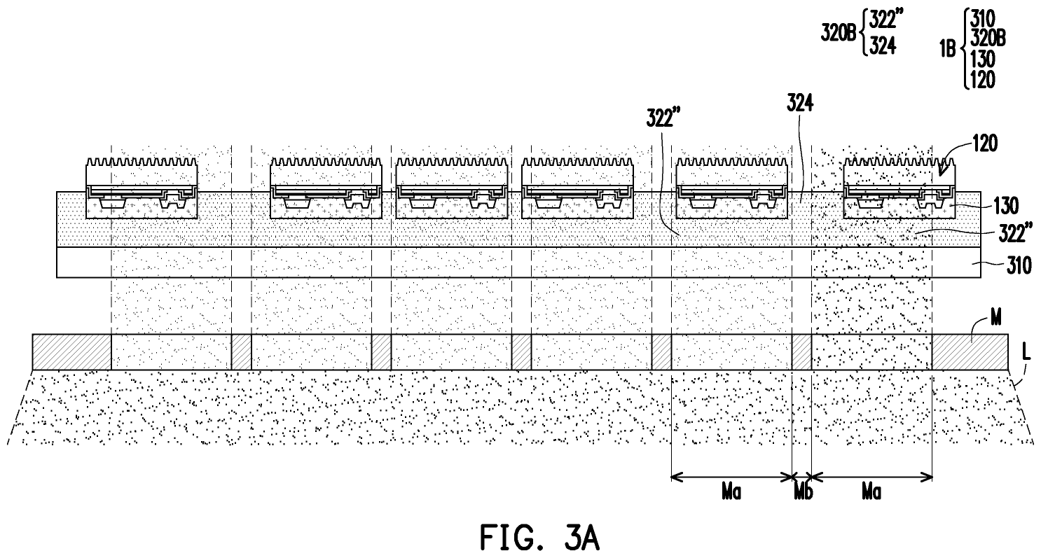

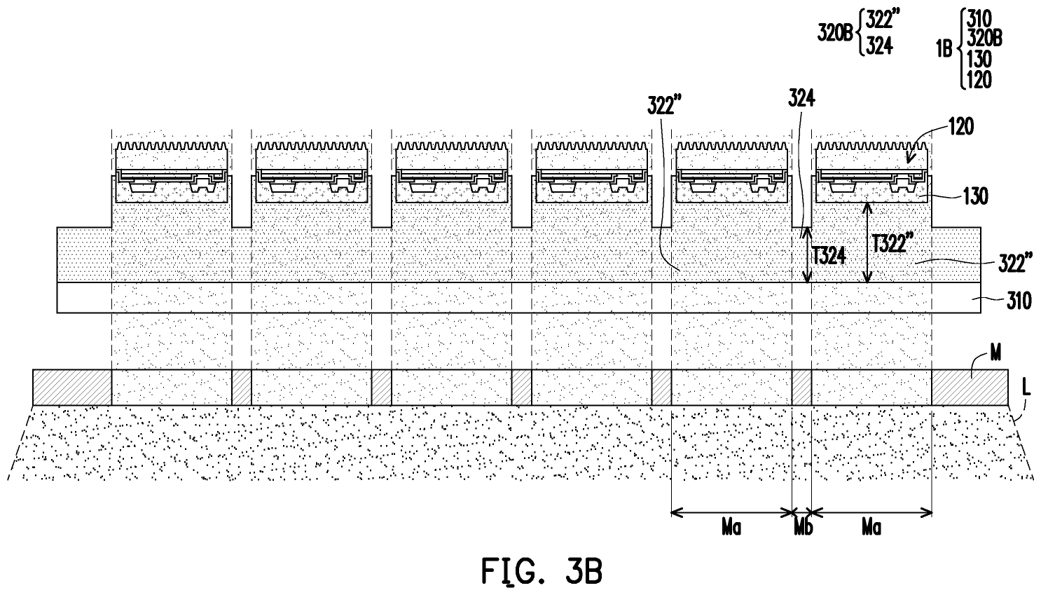

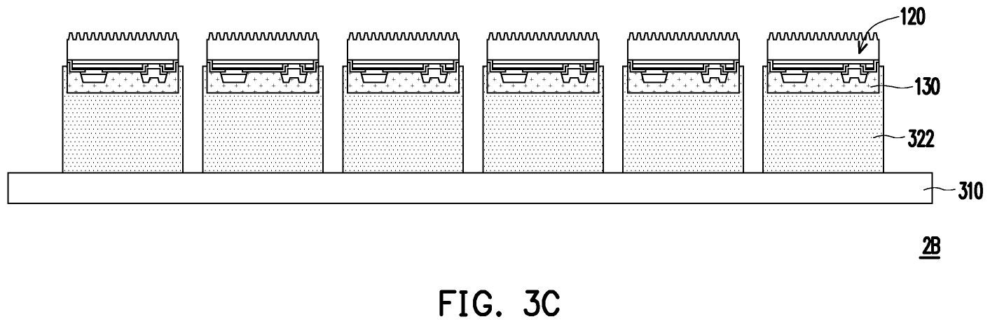

FIG. 3A to FIG. 3C are cross-sectional schematic views of a manufacturing process of a light emitting element array substrate according to yet another embodiment of the disclosure. A manufacturing method of a light emitting element array substrate 2B shown in FIG. 3A to FIG. 3C may be used to replace the manufacturing method of the light emitting element array substrate 2 shown in FIG. 1D to FIG. 1E. The manufacturing method of the light emitting element array substrate 2B will be described below with reference to FIG. 3A to FIG. 3C.

Please refer to FIG. 3A. A second adhesive layer 320B of a light emitting element array substrate 1B has the first areas 322″ respectively corresponding to the light emitting elements 120 and the second area 324 between the first areas 322″. In the embodiment, the material of the second adhesive layer 320B of the light emitting element array substrate 1B may have ultraviolet light and/or thermoplastic capabilities. In other words, the second adhesive layer 320B may be cured/deformed under the influence of ultraviolet light and/or heat.

Please refer to FIG. 3A and FIG. 3B. In the embodiment, the mask M may be provided. The mask M has the first mask areas Ma corresponding to the first areas 322″ of the second adhesive layer 320B and the second mask area Mb corresponding to the second area 324 of the second adhesive layer 320B, wherein one of the first mask area Ma and the second mask area Mb (for example, the first mask area Ma) is light transmissive, and the other one of the first mask area Ma and the second mask area Mb (for example, the second mask area Mb) is non-light transmissive. Then, the exposure process is performed on the second adhesive layer 320B using the mask M, wherein the beam L (for example, ultraviolet light) irradiates the first areas 322″ of the second adhesive layer 320B without irradiating the second area 324. The irradiated first area 322″ is deformed and becomes thicker, and a thickness T322″ of the irradiated first area 322″ is greater than a thickness T324 of the unirradiated second area 324.

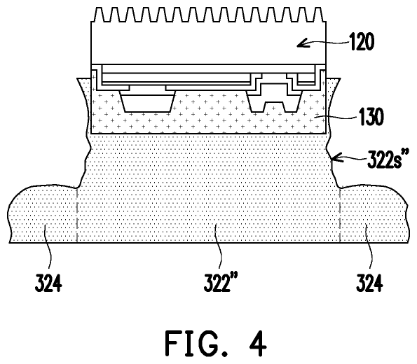

FIG. 4 is a partial cross-sectional enlarged schematic view of a light emitting element array substrate according to yet another embodiment of the disclosure. Please refer to FIG. 3B and FIG. 4. In an embodiment, since the first area 322″ of the second adhesive layer 320B is deformed by irradiation, a side wall 322s″ of the first area 322″ of the second adhesive layer 320B exhibit an irregular form.

Please refer to FIG. 3B and FIG. 3C. Then, the developing process is performed to remove the second area 324 of the second adhesive layer 320B, so that the first areas 322″ of the second adhesive layer 320B form the second adhesive members 322 separated from each other to form the light emitting element array substrate 2B.

It is worth mentioning that in the embodiment, since the material of the second adhesive layer 320B may have ultraviolet light and/or thermoplastic capabilities, as shown in FIG. 3A and FIG. 3B, during the process of performing the exposure process and the first area 322″ of the second adhesive layer 320B being irradiated by the beam L and deformed, the first area 322″ of the second adhesive layer 320B pulls the light emitting element 120 thereon back to a predetermined position corresponding to the first mask area Ma of the mask M. Thereby, the offset of the light emitting element 120 can be further reduced.

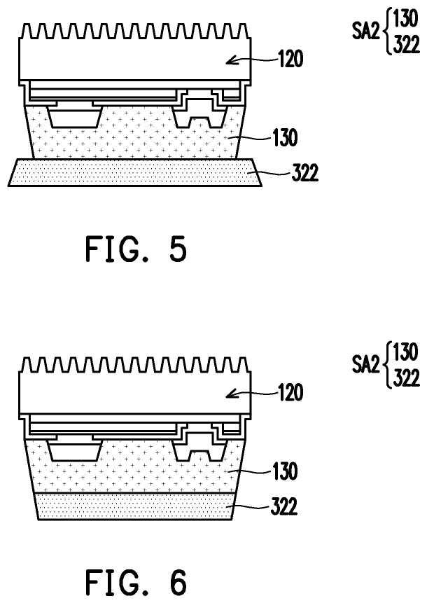

FIG. 5 is a partial cross-sectional enlarged schematic view of a light emitting element array substrate according to still another embodiment of the disclosure. In the embodiment of FIG. 5, the first adhesive member 130 of each adhesive structure SA2 is located between the second adhesive member 322 and the corresponding light emitting element 120, and the second adhesive member 322 exceeds the first adhesive member 130.

FIG. 6 is a partial cross-sectional enlarged schematic view of a light emitting element array substrate according to an embodiment of the disclosure. In the embodiment of FIG. 6, the first adhesive member 130 of each adhesive structure SA2 is located between the second adhesive member 322 and the corresponding light emitting element 120, and the first adhesive member 130 is substantially flush with the second adhesive member 322.

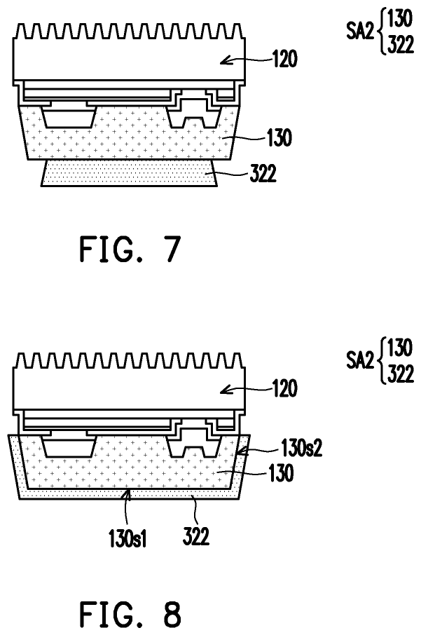

FIG. 7 is a partial cross-sectional enlarged schematic view of a light emitting element array substrate according to another embodiment of the disclosure. In the embodiment of FIG. 7, the first adhesive member 130 of each adhesive structure SA2 is located between the second adhesive member 322 and the corresponding light emitting element 120, and the first adhesive member 130 exceeds the second adhesive member 322.

FIG. 8 is a partial cross-sectional enlarged schematic view of a light emitting element array substrate according to yet another embodiment of the disclosure. In the embodiment of FIG. 8, the first adhesive member 130 of each adhesive structure SA2 is located between the second adhesive member 322 and the corresponding light emitting element 120, the first adhesive member 130 has a first surface 130s1 facing away from the corresponding light emitting element 120 and a side wall 130s2 connected to the first surface 130s1, and the second adhesive member 322 may conformally cover the first surface 130s1 and the side wall 130s2 of the first adhesive member 130.

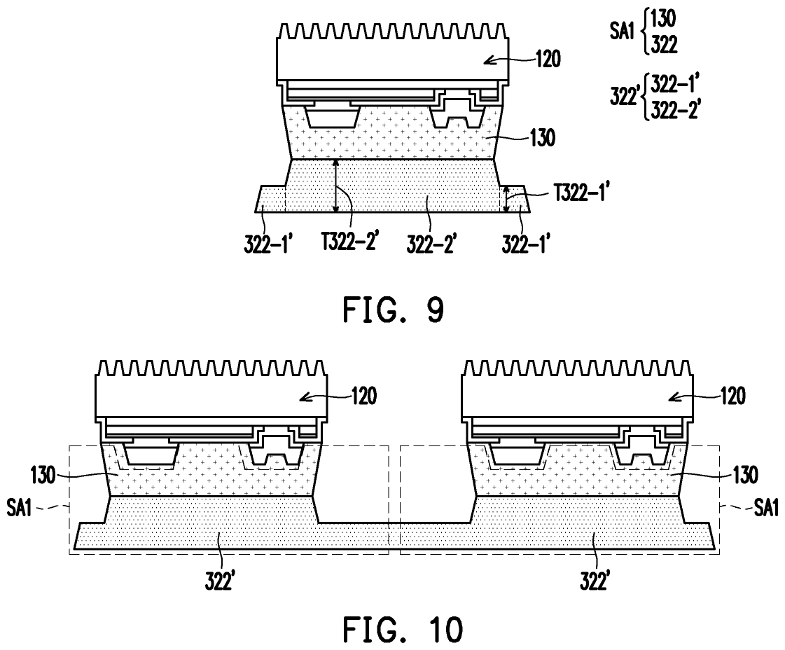

FIG. 9 is a partial cross-sectional enlarged schematic view of a light emitting element array substrate according to still another embodiment of the disclosure. In the embodiment of FIG. 9, the first adhesive member 130 of each adhesive structure SA1 is located between the second adhesive member 322′ and the corresponding light emitting element 120, the second adhesive member 322′ includes a deformation portion 322-2′ disposed on a base portion 322-1′ and connected to the base portion 322-1′, the deformation portion 322-2′ overlaps with the light emitting element 120, and the base portion 322-1′ extends outside the deformation portion 322-2′ and the light emitting element 120, wherein a thickness T322-2′ of the deformation portion 322-2′ is greater than a thickness T322-1′ of the base portion 322-1′.

FIG. 10 is a partial cross-sectional enlarged schematic view of a light emitting element array substrate according to an embodiment of the disclosure. In the embodiment of FIG. 10, the adhesive structures SA1 are connected to each other. The first adhesive member 130 of each adhesive structure SA1 is located between the second adhesive member 322′ and the corresponding light emitting element 120, the second adhesive members 322′ of the adhesive structures SA1 are directly connected, and the first adhesive members 130 of the adhesive structures SA1 are separated from each other.

What is claimed is:

1. A light emitting element array substrate, comprising:
a temporary storage base;
a plurality of light emitting elements, disposed on the temporary storage base; and
a plurality of adhesive structures, respectively located on the light emitting elements, wherein each of the adhesive structures comprises a first adhesive member and a second adhesive member stacked on each other.

2. The light emitting element array substrate according to claim 1, wherein one of the light emitting elements comprises a first semiconductor layer, a second semiconductor layer, an active layer disposed between the first semiconductor layer and the second semiconductor layer, and a plurality of electrodes respectively electrically connected to the first semiconductor layer and the second semiconductor layer, and one of the adhesive structure and the electrodes of the light emitting element are disposed on a same side of the active layer of the light emitting element.

3. The light emitting element array substrate according to claim 1, wherein the adhesive structures are disposed between the light emitting elements and the temporary storage base.

4. The light emitting element array substrate according to claim 1, wherein the light emitting elements are disposed between the adhesive structures and the temporary storage base.

5. The light emitting element array substrate according to claim 4, further comprising:
an adhesive layer, disposed on the temporary storage base, wherein the light emitting elements are disposed on the adhesive layer, the light emitting elements are located between the adhesive structures and the adhesive layer, and the adhesive layer is located between the light emitting elements and the temporary storage base.

6. The light emitting element array substrate according to claim 1, wherein the adhesive structures are separated from each other.

7. The light emitting element array substrate according to claim 1, wherein the adhesive structures are connected to each other.

8. The light emitting element array substrate according to claim 7, wherein the first adhesive member of each of the adhesive structures is located between the second adhesive member and the corresponding light emitting element, a plurality of second adhesive members of the adhesive structures are directly connected, and a plurality of first adhesive members of the adhesive structures are separated from each other.

9. The light emitting element array substrate according to claim 1, wherein the first adhesive member of each of the adhesive structures is located between the second adhesive member and the corresponding light emitting element, and the second adhesive member exceeds the first adhesive member.

10. The light emitting element array substrate according to claim 1, wherein the first adhesive member of each of the adhesive structures is located between the second adhesive member and the corresponding light emitting element, and the first adhesive member is substantially flush with the second adhesive member.

11. The light emitting element array substrate according to claim 1, wherein the first adhesive member of each of the adhesive structures is located between the second adhesive member and the corresponding light emitting element, and the first adhesive member exceeds the second adhesive member.

12. The light emitting element array substrate according to claim 1, wherein the first adhesive member of each of the adhesive structures is located between the second adhesive member and the corresponding light emitting element, the first adhesive member has a first surface facing away from the corresponding light emitting element and a side wall connected to the first surface, and the second adhesive member covers the first surface and the side wall of the first adhesive member.

13. The light emitting element array substrate according to claim 1, wherein the first adhesive member of each of the adhesive structures is located between the second adhesive member and the corresponding light emitting element, the second adhesive member comprises a deformation portion disposed on a base portion and connected to the base portion, the base portion extends outside the deformation portion and the light emitting element, and a thickness of the deformation portion is greater than a thickness of the base portion.

14. A manufacturing method of a light emitting element array substrate, comprising:
providing a plurality of first light emitting element supply substrates, wherein each of the first light emitting element supply substrates comprises a first temporary storage base, a light emitting element, and a first adhesive member, and the first adhesive member is disposed between the light emitting element and the first temporary storage base;
providing a second temporary storage base and a first adhesive layer on the second temporary storage base, wherein an area of the second temporary storage base is larger than an area of the first temporary storage base;
transposing a plurality of light emitting elements and a plurality of first adhesive members of the first light emitting element supply substrates to the first adhesive layer on the second temporary storage base to form a second light emitting element supply substrate, wherein the second light emitting element supply substrate comprises the second temporary storage base, the first adhesive layer, the light emitting elements, and the first adhesive members, and each of the light emitting elements is located between the corresponding first adhesive member and the first adhesive layer;
providing a third temporary storage base and a second adhesive layer on the third temporary storage base; and
transposing the light emitting elements and the first adhesive members of the second light emitting element supply substrate to the second adhesive layer on the third temporary storage base, so that the first adhesive members are located between the light emitting elements and the second adhesive layer, and the second adhesive layer is located between the first adhesive members and the third temporary storage base.

15. The manufacturing method of the light emitting element array substrate according to claim 14, further comprising:
patterning the second adhesive layer on the third temporary storage base to form a plurality of second adhesive members separated from each other, wherein the first adhesive members are located between the light emitting elements and the second adhesive members, and the second adhesive members are located between the first adhesive members and the third temporary storage base.

16. The manufacturing method of the light emitting element array substrate according to claim 14, wherein the second adhesive layer has a plurality of first areas respectively corresponding to the light emitting elements and a second area between the first areas, the manufacturing method of the light emitting element array substrate further comprising:
providing a mask having a first mask area corresponding to the first areas of the second adhesive layer and a second mask area corresponding to the second area of the second adhesive layer, wherein one of the first mask area and the second mask area is light transmissive, and other one of the first mask area and the second mask area is non-light transmissive;
performing an exposure process on the second adhesive layer using the mask; and
performing a development process to remove the second area of the second adhesive layer, so that the first areas of the second adhesive layer form a plurality of second adhesive members separated from each other.

17. The manufacturing method of the light emitting element array substrate according to claim 16, further comprising:
performing a thermal curing process on the first adhesive members and the second adhesive members.
